(19) United States
(12) Patent Application Publication
(10) Pub. No.: US 2006/0208772 A1
(43) Pub. Date: Sep. 21, 2006

(54) Semiconductor integrated circuit and noise-reduction method thereof

(75) Inventor: Rikizo Nakano, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/178,371

(22) Filed: Jul. 12, 2005

(30) Foreign Application Priority Data
Mar. 18, 2005 (JP) 2005-080702

(51) Int. Cl. H03B 1/00

(52) U.S. Cl. 327/108

(57) ABSTRACT

Regarding a semiconductor integrated circuit equipped with elements or circuits producing state changes upon receiving a common input, timings to produce state changes by the input are displaced. This is achieved by configuring a plurality of elements or circuits (input buffer circuits) with different threshold levels (threshold voltages Vtha, Vthb, Vthc) such that the state changes are produced at different timings (t1, t2, t3) in accordance with the threshold levels, in the case where a common input (input voltage Vin) is applied to these elements or circuits simultaneously. The elements are transistors, whereas the circuits are comprised of CMOS circuits, and the threshold levels are set by constants or the like.

### BACKGROUND OF THE INVENTION

1. Field of the Invention

The present invention relates to a semiconductor integrated circuit comprising a plurality of elements or circuits that produces electrical state changes with an input such as a flow-through current flowing among elements of a CMOS (Complementary Metal Oxide Semiconductor) circuit, for example, and more specifically, relates to a semiconductor integrated circuit equipped with a plurality of elements, or a circuit such as a CMOS circuit that simultaneously produces electrical state changes with a common input, and to a noise reduction method thereof.

2. Description of the Related Art

As an example of semiconductor integrated circuits, in an LSI (Large Scale Integration), multiple pins are implemented, higher density is achieved, and many input-output (I/O) circuits are implemented. When these I/O circuits simultaneously perform switching with an input signal, the impact of noise caused by the switching cannot be ignored. This switching noise is mainly produced by fluctuations in a power source or by fluctuations in GND potential caused by a switching current accompanied by the input switching.

The impact of noise caused by simultaneous switching of elements or circuits depends on the rise and fall of the input signal, the amplitude of the input signal, and the number of signals switching simultaneously. Especially, in a signal transmission channel of multiple bits such as a data bus, many signals switch simultaneously at the same timing. The more the number of simultaneous continuity increases, the greater the switching noise arises. For instance, in a CMOS circuit, a current flows at the time of signal switching, and in the case where a section (step) of constant level exists in the middle level because of reflected wave forms, the flow-through current flows at the middle level position (Δt in FIG. 6), which also constitutes a noise source.

With regard to such semiconductor integrated circuits, for example, there is Japanese Patent Application Laid-Open Publication No. H05(1993)-235736 in which the logic threshold levels of a CMOS circuit differentiate the switching speed.

By the way, in the case where a semiconductor integrated circuit includes many elements or circuits that conduct simultaneously upon receiving a common input, a current that flows from the power source toward the ground side via the semiconductor integrated circuit becomes larger as the number of continuity of the elements or the circuits increases. The noise depends on the magnitude and the variation of this current value, so that suppressing the current value can reduce the noise. However, with semiconductor integrated circuits that achieve greater functionality and versatility through the implementation of multiple pins and high-density packing, there is a risk that the circuit functions may be lost by simply suppressing the current.

The Japanese Patent Application Laid-Open Publication No. H05(1993)-235736 discloses, in its paragraph Nos. 0020, 0021, 0026, and in its FIGS. 2, 4, etc., that the logic threshold levels of the CMOS circuit differentiate the switching speed, however, the application has neither disclosed nor suggested noise generation that is dependent on the current, the noise control, and the solution method thereof.

### SUMMARY OF THE INVENTION

The present invention relates to a semiconductor integrated circuit equipped with elements or circuits that produce state changes upon receiving a common input, and its object is to displace timings in which state changes are produced by the input.

Further, the present invention relates to a semiconductor integrated circuit equipped with elements and circuits that produce state changes upon receiving a common input, and its object is to reduce noise caused by the state changes produced by the input.

To attain the above objects, according to a first aspect of the present invention, there is provided a semiconductor integrated circuit comprising a plurality of elements or circuits with different threshold levels, configured to produce state changes at different timings in accordance with the threshold levels, in the case where a common input is applied to those elements or circuits simultaneously.

According to such a configuration, a plurality of elements or circuits produces state changes by inputs, and a current flows in accordance with the state changes. By setting different threshold levels for those plurality of elements or circuits, if a common input is received, state changes are produced at different timings depending on the threshold levels having been set thereat, and subsequently the timings when the currents flow become different to each other so that peak values will not be superposed owing to the timing difference. As a result of this, a current flowing from the power source into the semiconductor integrated circuit is significantly reduced and its fluctuation is also suppressed. Accordingly, noise generation is suppressed and even if the noise is produced, its amplitude is substantially reduced.

In this semiconductor integrated circuit, the elements may be comprised of transistors.

In this semiconductor integrated circuit, the circuits may be comprised of CMOS circuits.

In this semiconductor integrated circuit, the threshold levels may be set using constants of the elements or circuits.

In this semiconductor integrated circuit, the threshold levels may be set by concentration of impurities in substrate area of the elements.

In this semiconductor integrated circuit, the threshold levels may be set by the distance between the substrate area in which a channel of the elements is formed and a gate of the elements.

In this semiconductor integrated circuit, a threshold level setting circuit may be further provided in order to set different threshold levels to the elements or circuits.

To attain the above objects, according to a second aspect of the present invention, there is provided a semiconductor integrated circuit comprising a plurality of circuits that produce state changes in accordance with inputs, the circuits further comprising a plurality of actuating pairs consisting of a first transistor to which different threshold voltages are inputted and a second transistor to which an input voltage is applied; and current mirror circuits provided for each of the actuating pairs to constitute loads of the first and second transistors.

To attain the above objects, according to a third aspect of the present invention, there is provided a semiconductor integrated circuit comprising a single or a plurality of CMOS circuits that produce state changes in accordance with inputs, wherein the CMOS circuit has been set with different threshold levels such that state changes are produced at different timings in accordance with difference of the threshold levels, upon receiving a common input simultaneously.

To attain the above objects, according to a fourth aspect of the present invention, there is provided a semiconductor integrated circuit comprising a single or a plurality of CMOS circuits that produce state changes in accordance with inputs, wherein the CMOS circuit has been set with different threshold levels such that superposition of peak values of flow-through currents flowing among the elements are avoided by differentiating timings of the rise and fall of the flow-through currents in accordance with difference of the threshold levels, upon receiving a common input simultaneously.

To attain the above objects, according to a fifth aspect of the present invention, there is provided a noise reduction method for a semiconductor integrated circuit comprising a plurality of elements or circuits, the method setting different threshold levels to the elements or circuits such that state changes are produced at different timings in accordance with the threshold levels, upon receiving a common input simultaneously.

According to such a configuration, as has been described, by differentiating the threshold levels, even though a common input is received simultaneously, states changes are produced at different timings in accordance with the different threshold levels, so that generation of noise caused by current values accompanied by the state changes or by the variance can be suppressed and noise amplitude can be reduced.

(1) Therefore, according to the present invention, since the semiconductor integrated circuit comprising a plurality of elements or circuits includes the elements or circuits with different threshold levels, even though a common input is received simultaneously, states changes are produced at different timings in accordance with the different threshold levels, so that the superposition of the peak value of the current accompanied by the state changes can be prevented, and consequently the current value and its variance can be reduced.

(2) Furthermore, according to the present invention, by reducing the current value and its variance, suppression of noise generation and reduction of noise amplitude can be achieved, and accordingly a malfunction of semiconductor integrated circuits including a plurality of elements and circuits can be prevented, and thus reliability can be enhanced.

### BRIEF DESCRIPTION OF THE DRAWINGS

The above and other objects, aspects, features and advantages of the present invention will become more apparent from the following detailed description when taken in conjunction with the accompanying drawings, in which:

FIG. 1 is a circuit diagram showing a semiconductor integrated circuit according to a first embodiment of the present invention.

FIG. 2 is a circuit diagram showing an input buffer circuit;

FIG. 3 is a diagram showing (A) an input voltage to an input buffer circuit and (B) a flow-through current;

FIG. 4 is a diagram showing a flow-through current produced in an LSI;

FIG. 5 is a diagram showing a behavior in the case where threshold levels are differentiated;

FIG. 6 is a diagram showing another behavior in the case where threshold levels are differentiated;

FIG. 7 is a diagram showing a CMOS circuit in order to explain the setting of threshold levels;

FIG. 8 is a circuit diagram showing a semiconductor integrated circuit according to a second embodiment of the present invention;

FIG. 9 is a circuit diagram showing a semiconductor integrated circuit according to a third embodiment of the present invention;

FIG. 10 is a circuit diagram showing an input buffer circuit;

FIG. 11 is a circuit diagram showing a configuration example of a threshold level setting circuit;

FIG. 12 is a circuit diagram showing a semiconductor integrated circuit in which the threshold level setting circuit is configured as an external circuit;

FIG. 13 is a circuit diagram showing a semiconductor integrated circuit according to a fourth embodiment of the present invention; and

FIG. 14 is a block diagram showing a semiconductor integrated circuit according to a fifth embodiment of the present invention.

### DETAILED DESCRIPTION OF THE PREFERRED EMBODIMENTS

### First Embodiment

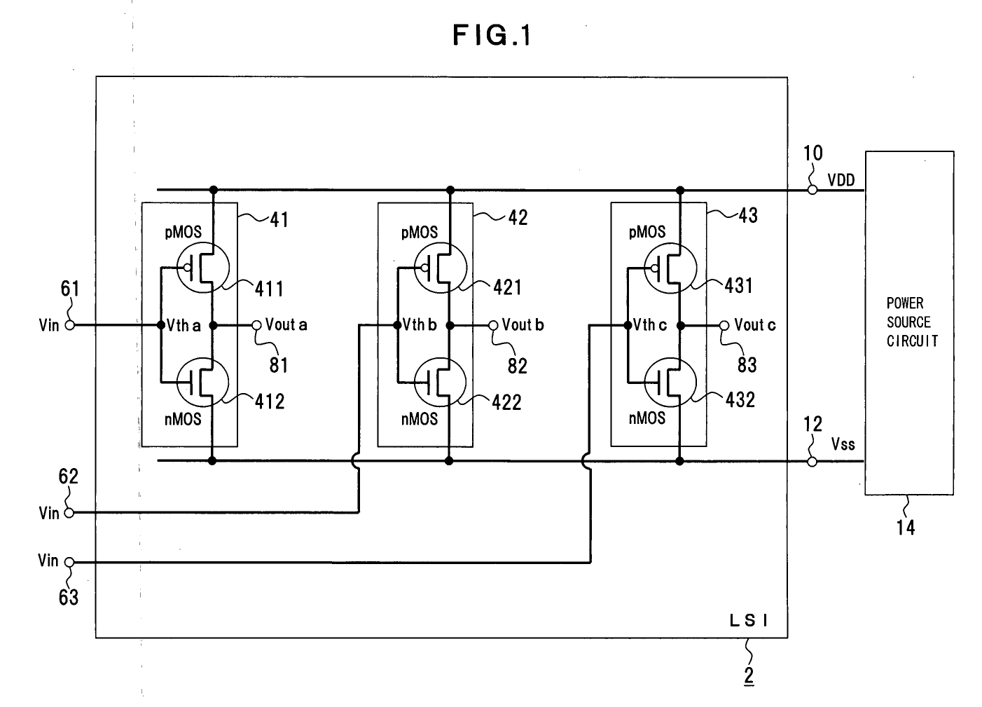

A first embodiment of the present invention will be described with reference to FIG. 1. FIG. 1 is a circuit diagram showing a semiconductor integrated circuit according to a first embodiment.

As such semiconductor integrated circuits, for example, in a LSI2, three pairs of input buffer circuits 41, 42, 43 are provided, for instance, as a plurality of input buffer circuits. To each input buffer circuit 41, 42, 43, threshold voltages Vtha, Vthb, Vthc, are set respectively as different threshold levels, and magnitude of these threshold voltages is set as Vtha<Vthb<Vthc, for example. To input terminals 61, 62, 63, an input voltage Vin is applied, for example. This input voltage Vin is a voltage that rises or falls over a certain time period. Upon receiving such input voltage Vin, each input buffer circuit 41, 42, 43 produces an electrical state change, and output voltages Vouta, Voutb, Voutc, for example, are obtained from output terminals 81, 82, 83 respectively. In this case, to each input buffer circuit 41, 42, 43, voltages VDD, Vss (VDD>Vss) are applied from a power source circuit 14 connected to power source terminals 10, 12 of the LSI2.

In this LSI2, the input buffer circuit 41 is comprised of an inverter constituted of a first transistor 411 and a second transistor 412. In this embodiment, the transistor 411 is comprised of a P channel MOS (Metal Oxide Semiconductor) transistor, whereas the transistor 412 is comprised of a N channel MOS (Metal Oxide Semiconductor) transistor, and these transistors 411, 412 constitute the inverter for a CMOS circuit. At the gate to which each transistor 411, 412 is connected in common, the input terminal 61 is formed, and to which the input voltage Vin is applied. And at the drain to which each transistor 411, 412 is connected in common, the output terminal 81 is formed, and from which the output voltage Vouta is obtained. To the source of the transistor 411, the power source circuit 14 is connected and the voltage VDD is applied thereto, while to the source of the transistor 412, the power source circuit 14 is connected and the voltage Vss is applied thereto. The output voltage Vouta obtained from the output terminal 81 becomes a high level (voltage VDD) when the transistor 411 conducts, and becomes a low level (voltage Vss) when the transistor 412 conducts.

In addition, the input buffer circuit 42 is comprised of first and second transistors 421, 422, whereas the input buffer circuit 43 is comprised of first and second transistors 431, 432. The configurations and connections of these elements, and the connection relationship with the power source circuit 14 are the same as those of the input buffer circuit 41, except that the threshold voltages Vthb, Vthc are different.

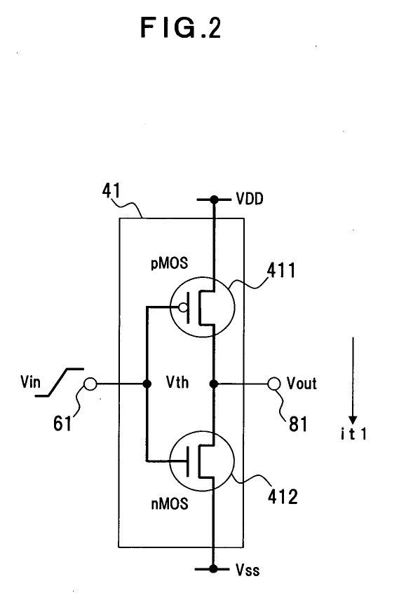

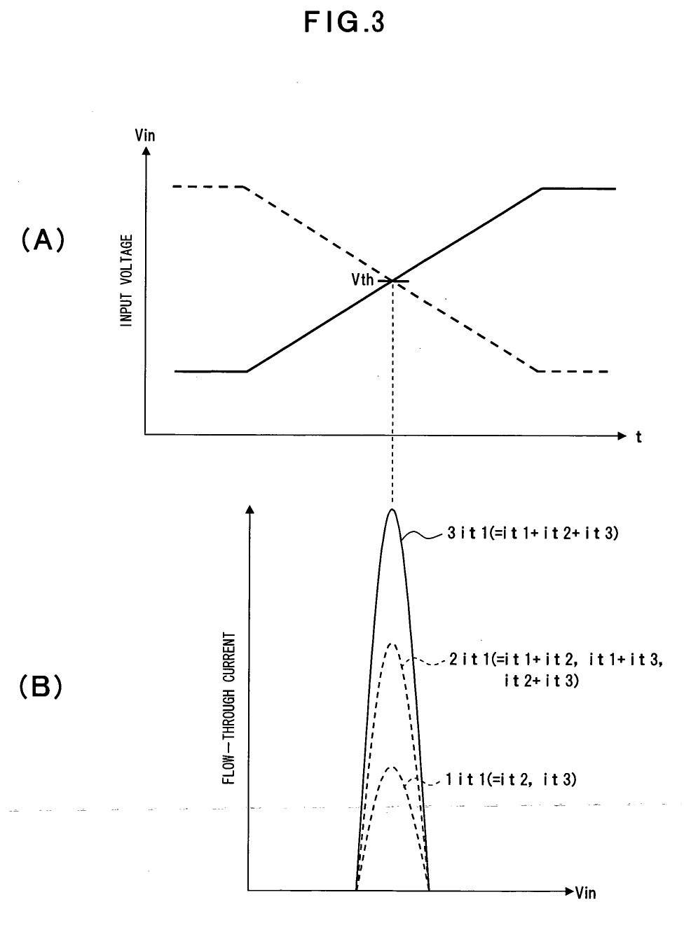

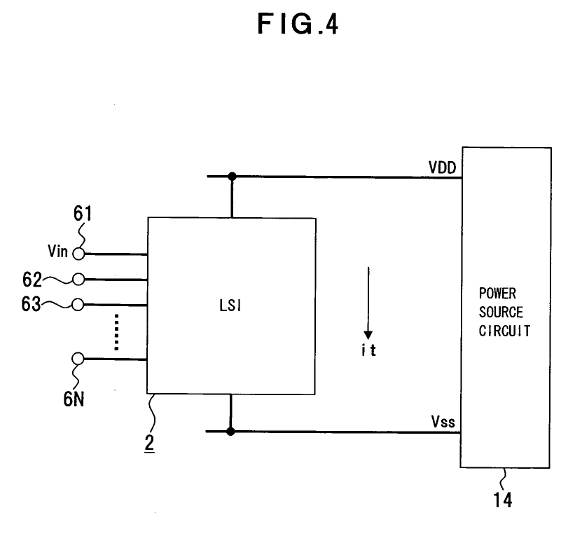

Before the explanation of behaviors of these input buffer circuits 41, 42, 43, a behavior in the case where the threshold levels are the same will be described with reference to FIGS. 2, 3 and 4. FIG. 2 is a circuit diagram showing a basic configuration of an input buffer circuit; FIG. 3 is a diagram showing (A) an input voltage and (B) a flow-through current, in the case where the threshold levels are the same; and FIG. 4 is a diagram showing relationship with the power source circuit.

Assuming that a threshold voltage Vth has been set to the input buffer circuit 41 (FIG. 2), if the input voltage Vin that varies from a low level below the threshold voltage Vth to a level above the threshold voltage Vth is applied to the input terminal 61, as shown in (A) of FIG. 3, then the transistor 411 conducts at a level lower than the threshold voltage Vth, and the transistor 412 conducts at a level higher than the threshold voltage Vth. That is, in the input buffer circuit 41, because of relative relationship between the input voltage Vin and the threshold voltage Vth, an electrical state change is produced, which appears in the output voltage Vout, and at the time when conductive states switch over, a flow-through current it1 flows in the transistors 411, 412, as shown in (B) of FIG. 3.

In this case, assuming that the same threshold voltage Vth of the above-described input buffer circuit 41 has been set to the input buffer circuits 42, 43 as well, then a flow-through current when the input buffer circuits 42, 43 produce electrical state changes simultaneously, becomes value of the sum of flow-through currents it1, it2 in the respective input buffer circuits 41, 42. In addition, a flow-through current when the input buffer circuits 41, 42, 43 produce electrical state changes simultaneously, becomes value of the sum of flow-through currents it1, it2, it3 (it1+it2+it3) in the respective input buffer circuits 41, 42, 43.

In this case, in the LSI2 including the input buffer circuits 41 to 43 having the same threshold level, a flow-through current “it” flows from the power source circuit 14 toward the LSI2, as shown in FIG. 4, and its max value becomes as follows;
it=it1 +it2+it3 (1)
In this case, supposing that it1=it2=it3, then “it” becomes equal to 3it1 (it=3it1) as shown in (B) of FIG. 3, and the peak value increases in proportion to N that is the number of the input buffer circuits implemented, and its fluctuation (dit/dt) increases in proportion to the increment as well, which causes noise and increases the amplitude of the noise generated.

Such behavior occurs in the same way, not only in the case where the input voltage Vin increases over the time t as shown in (A) of FIG. 3, but also in the case where the input voltage decreases over the time t, as shown by dashed lines. In the input buffer circuit 41, this behavior occurs when the transistor 411 shifts from a cutoff state to a conduction state as well as the transistor 412 shifts from a conduction state to a cutoff state. Such behavior also occurs in the input buffer circuits 42, 43, so that in the three input buffer circuits 41 to 43, the flow-through current that are added in the same way (it=3it1) flows from the power source circuit 14 (FIG. 4).

The CMOS circuit constituting the input buffer circuits 41, 42, 43 flows current at signal switching, i.e., the circuit flows current in the case where the input voltage Vin increases from a low level to exceed the threshold voltage Vth, or in the case where the input voltage Vin decreases from a high level to fall short of the threshold voltage Vth, so that if the threshold levels are the same, then the timing of current flowing is consistent with the rise (tr) or the fall (tf) of the flow-through current. Therefore, if the threshold level of each input buffer circuit 41, 42, 43 is the same for a plurality of inputs that is applied simultaneously to the input buffer circuits 41, 42, 43, then the timings of flow-through current coincide with each other, thereby its current value becomes larger by the superposition of the flow-through current, and the noise amplification caused by the current fluctuation is all the more enhanced, since the fluctuation increases proportionally to the superposed flow-through current. The enhanced amplitude of noise can have a detrimental effect on adjoining circuits and semiconductor integrated circuits, and become a cause of inducing a malfunction.

Such inconveniences as noise generation caused by electrical state changes can be avoided by setting different threshold levels so that the timings in which electrical state changes are produced are differentiated. Therefore, by setting different threshold levels, the cause of noise generation is eliminated in the input buffer circuits 41, 42, 43 as shown in FIG. 1.

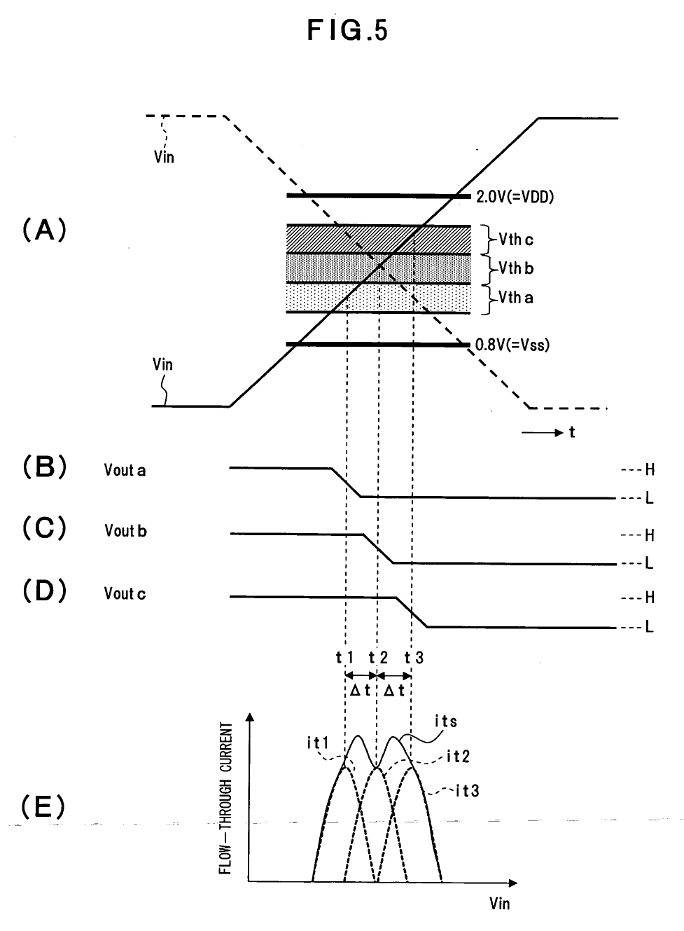

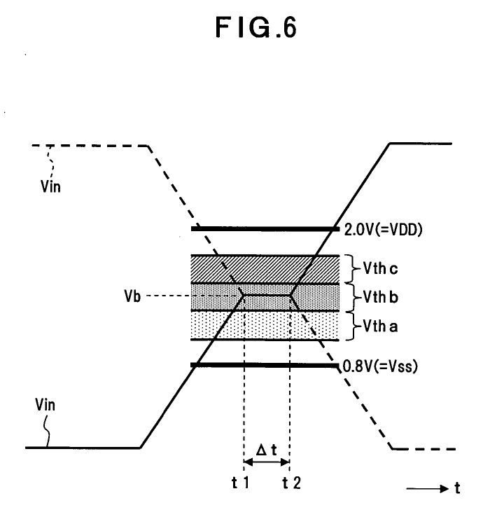

Next, behaviors of the input buffer circuits 41, 42, 43 in which different threshold levels are set will be described with reference to (A) to (E) of FIG. 5 and FIG. 6. (A) to (E) of FIG. 5 are diagrams showing the behaviors of the input buffer circuits of FIG. 1, and FIG. 6 is a diagram showing relationship between the input voltage Vin and the threshold levels.

As shown in (A) of FIG. 5, the input voltage Vin is a voltage that fluctuates with increase or decrease of its level over the time t. The input voltage Vin indicated in solid lines is a voltage that increases over the time t, and the input voltage Vin indicated by dashed lines is a voltage that decreases over the time t. To this input voltage Vin, the power source voltages VDD, Vss are set, and within the range of these power source voltages VDD, Vss, the threshold voltages, Vtha, Vthb, Vthc are set. These threshold voltages Vtha, Vthb, Vthc are voltages that have a certain voltage range.

When the input voltage Vin is applied in common to the input terminals 61, 62, 63, then due to relative relationship between level fluctuation (level fluctuation over time) of this input voltage Vin and the threshold voltages Vtha, Vthb, Vthc, electrical state changes are produced in the input buffer circuits 41, 42, 43. Since the threshold voltages Vtha, Vthb, Vthc have been differentiated in the setting (in this case, Vtha<Vthb<Vthc), there arise differences in the timings to produce electrical state changes.

Specifically, when the input voltage Vin reaches the threshold voltage Vtha, the transistor 411 shifts from the conduction state to the cutoff state, whereas the transistor 412 shifts from the cutoff state to the conduction state, and as shown in (B) of FIG. 5, the output voltage Vouta is produced as an electrical state change at the output terminal 81. Further, when the input voltage Vin reaches the threshold voltage Vthb, then the transistor 421 shifts from the conduction state to the cutoff state, whereas the transistor 422 shifts from the cutoff state to the conduction state, and the output voltage Voutb is produced as an electrical state change at the output terminal 82, as shown in (C) of FIG. 5. Furthermore, when the input voltage Vin reaches the threshold voltage Vthc, then the transistor 431 shifts from the conduction state to the cutoff state, whereas the transistor 432 shifts from the cutoff state to the conduction state, and the output voltage Voutc is produced at the output terminal 83 as an electrical state change, as shown in (D) of FIG. 5. In this case, since each input buffer circuit 41, 42, 43 constitutes the inverter, an inverse output of the input can be obtained.

In this case, assuming that a voltage difference between the threshold voltage Vtha and the threshold voltage Vthb as ΔV; a voltage difference between the threshold voltage Vthb and the threshold voltage Vthc as ΔV, then from relative relationship of level fluctuations over time between these voltage differences ΔV and the input voltage Vin, the timings in which electrical state changes are produced in the input buffer circuits 41, 42, 43, become as t1, t2, t3, and thus electrical state changes are produced with time difference Δt (t2−t1 or t3−t2). T1, t2, t3 are the timings in which the output voltages Vouta, Voutb, Voutc are produced.

By the way, (B) to (E) of FIG. 5 referenced in the above description describe the case in which the input voltage Vin increases over the time, and the same behavior occurs for the input voltage Vin indicated by dashed lines in (A) of FIG. 5. In that case, with the transistors 411, 421, 431 shifting from the cutoff state to the conduction state, and with the transistors 412, 422, 432 shifting from the conduction state to the cutoff state, the output voltages Vouta, Voutb, Voutc change from L level to H level. However, since different threshold voltages Vtha, Vthb, Vthc are set thereto, the timings in which electrical state changes are produced in the input buffer circuits 41, 42, 43 become as t1, t2, t3, and thus these timings t1, t2, t3 become the timings in which state changes are produced in the output voltages Vouta, Voutb, V-outc.

Assuming that flow-through currents produced in the input buffer circuits 41, 42, 43 as it1, it2, it3, then these it1, it2, it3 correspond to the timings t1, t2, t3, and produce peak values with the time difference At. Because of this, a flow-through current ‘its’ that is the added flow-through currents it1, it2, it3 flowing from the power source circuit 14 into the input buffer circuits 41, 42, 43, becomes a value that has two peak values slightly higher than the flow-through current it1 or it2, with a central value of the peak value of the flow-through current it2. Therefore, even if the flow-through currents it1, it2, it3 are produced in all the input buffer circuits 41, 42, 43, its value has two peak values only slightly higher than the flow-through current it1 or it2, so that its fluctuation (dit/dt) becomes smaller. Because of this, noise generation caused by the flow-through current ‘it’ can be suppressed, and accordingly malfunctions caused by the noise of LSI2 can be avoided.

Here, assuming that the input voltage Vin applied to the input terminals 61, 62, 63 as digital signals of three bits, then, the input signal Vin represents values of “000”, “001”, “010”, “011”, “100”, “101”, “110”, “111”. In this case, by specifying that “0” indicates that Vin=low (L) level, while “1” indicates that Vin=high (H) level, and by allocating the highest digit of three bits to the input terminal 61 of the input buffer circuit 41; the middle digit to the input terminal 62 of the input buffer circuit 42; and the lowest digit to the input terminal 63 of the input buffer circuit 43, then, for instance, when the input voltage Vin shifts from “000” to “001”, the electrical state in the input buffer circuit 43 corresponding to the lowest digit changes. In this case, the flow-through current it3 flows only in the input buffer circuit 43. Moreover, when the input voltage Vin shifts from “011” to “100”, for example, then the highest digit “0” changes to “1”, whereas both “1” of the middle digit and the lowest digit change to “0”, so that electrical states of all the input buffer circuits 41, 42, 43 change accordingly, thereby the flow-through currents it1, it2, it3 flow. As has been described, peak value of each flow-through current it1, it2, it3 is produced at displaced timing, so that the peak value of “its” that is the added flow-through currents can be suppressed, and since its fluctuation (dis/dt) becomes smaller, malfunctions caused by noise generation produced by the flow-through current “it” can be prevented.

By the way, regarding the input voltage Vin applied to the input terminals 61, 62, 63, as shown in FIG. 6, if there exists a voltage Vb whose level is continuous (voltage step) during a time Δt, and if this voltage Vb is within the threshold voltage Vthb, then the flow-through current it2 flows continuously in the corresponding input buffer circuit 42. Here, since different threshold voltages Vtha, Vthc (≠Vthb) are set in the other input buffer circuits 41, 43, the timings to produce state changes are different therein. Because of this, there is no effect of the flow-through current it2; the peak value of the added flow-through currents “its” is suppressed low; and its fluctuation (dis/dt) becomes smaller, so that the noise can be suppressed, and eventually the above-described malfunctions can be prevented. Such behavior is the same for the input voltage Vin indicated by dashed lines.

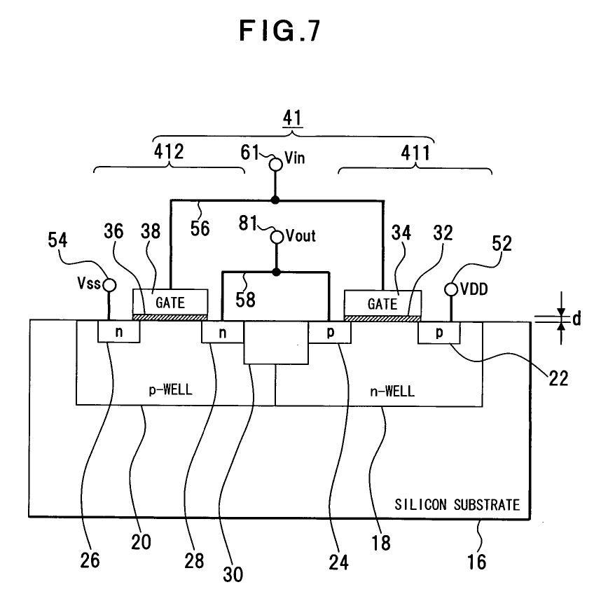

Next, settings of threshold voltages for the input buffer circuits 41, 42, 43 will be described with reference to FIG. 7. FIG. 7 is a cross-sectional view of the structure of a CMOS constituting the input buffer circuit 41.

As a semiconductor substrate, for example, in a silicon substrate 16, a N-well 18 that is a N-type semiconductor area and a P-well 20 that is a P-type semiconductor area are formed adjacent to each other to form a twin-well structure. In the N-well 18, a source 22 and a drain 24 are provided in the P-type semiconductor area, while in the P-well 20, a source 26 and a drain 28 are provided in the N-type semiconductor area. Between the drain 24 at the N-well 18 side and the drain 28 at the P-well 20 side, a separation insulating area 30 is provided spreading across the N-well 18 and the P-well 20, and-with this separation insulating area 30, the insulation between each drain 24, 28 is achieved. On the gap between the source 22 and the drain 24 on the N-well 18, a gate 34 is provided interposing an insulation layer 32 therebetween, while on the gap between the source 26 and the drain 28 on the P-well 20, a gate 38 is provided interposing an insulation layer 36 therebetween.

With such a P-N structure, the transistor 411 of the P-channel is comprised at the N-well 18 side, and the transistor 412 of the N-channel is comprised at the P-well 20 side. At the source 22, a feeding terminal 52 for feeding the voltage VDD is formed, while at the source 26, a feeding terminal 54 for feeding the voltage Vss is formed.

Subsequently, to the gates 34, 38, a common wiring conductor 56 is connected to form the input terminal 61, and to the drains 24, 28, a common wiring conductor 58 is connected to form the output terminal 81.

With such a CMOS structure, the threshold voltage Vtha of the transistors 411, 412 is determined by a concentration of impurities of the N-well 18 and the P-well 20 in the substrate area, so that by controlling the concentration of impurities, the threshold voltage can be set to a desirable voltage. The transistor 412 formed on the P-well 20 side can raise the threshold voltage Vtha by increasing the concentration of impurities of the P-well 20.

Furthermore, with such a CMOS structure, the channel of the transistors 411, 412 can vary the threshold voltage Vtha by thickness of a layer d of the insulating layers 32, 36. Therefore, through setting of the thickness of the layer d of the insulating layers 32, 36, the threshold voltage Vtha can be set to a desirable voltage.

Regarding the settings of such threshold voltage Vtha, if the input buffer circuits 42, 43 are comprised of similar CMOS structure, then those threshold voltages Vthb, Vthc can be set in the same manner. That is, in the CMOS structure, through the setting of concentration of impurities of the N-well 18, P-well 20, and through the setting of constants such as the thickness of the layer d of the insulating layers 32, 36, desirable threshold voltages Vtha, Vthb, Vthc can be set, and their levels can be set as Vtha<Vthb<Vthc.

### Second Embodiment

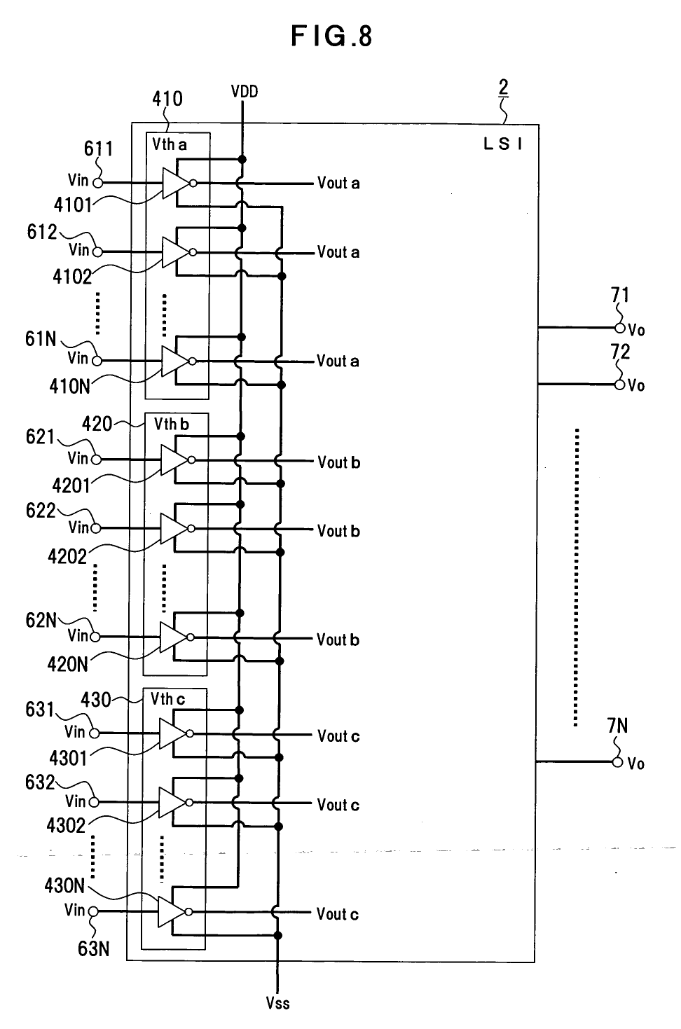

Next, a second embodiment of the present invention will be described with reference to FIG. 8. FIG. 8 is a diagram showing a configuration example of an LSI with a built-in input buffer circuit having different threshold levels.

In this LSI2, as a plurality of input buffer circuit blocks having different threshold levels, three pairs of input buffer circuit blocks 410, 420, 430 are provided, for example. Each input buffer circuit block 410, 420, 430 is comprised of input buffer circuits 4101, 4102, . . . 410N; input buffer circuits 4201, 4202, . . . 420N; and input buffer circuits 4301, 4302, . . . 430N, for example, as a plurality of input buffers. In this embodiment, to the input buffer circuit block 410, the threshold voltage Vtha is set; to 420, Vthb is set; and to 430, Vthc is set. Magnitude of threshold voltages is set as Vtha<Vthb<Vthc, for example.

In short, regarding this LSI2, in other words, each input buffer circuit block 410, 420, 430 is a grouping formed by setting different threshold voltages Vtha, Vthb, Vthc respectively to the input buffer circuits 4101, 4102, . . . 410N, 4201, 4202, . . . 420N, 4301, 4302, . . . 430N, which produce a state change on receiving the input voltage Vin at a common timing. That is, the input buffer circuits 4101, 4102, . . . 410N in which the common threshold voltage Vtha has been set are grouped as the input buffer circuit block 410; the input buffer circuits 4201, 4202, . . . 420N in which the common threshold voltage Vthb has been set are grouped as the input buffer circuit block 420; and the input buffer circuits 4301, 4302, . . . 430N in which the common threshold voltage Vthc has been set are grouped as the input buffer circuit block 430.

Subsequently, in this LSI2, to input terminals 611, 612, . . . 61N, 621, 622, . . . 62N, 631, 632, . . . 63N, for example, the input voltage Vin is applied as input such as digital signals of multiple bits; the output voltages Vouta, Voutb, Voutc can be obtained in each input buffer circuit block 410, 420, 430; and output voltages Vo can be obtained from output terminals 71, 72, . . . 7N.

According to such a configuration, as shown in (A) of FIG. 5, if the input voltage Vin is applied in common to the input terminals 611, 612, . . . 61N, 621, 622, . . . 62N, 631, 632, . . . 63N, then due to the relationship of magnitude between this input voltage Vin and the threshold voltages Vtha, Vthb, Vthc, electrical state changes are produced in the input buffer circuit blocks 410, 420, 430. Since the threshold voltages Vtha, Vthb, Vthc have been differentiated in the setting, there arise differences in the timings to produce electrical state changes.

Specifically, if the input voltage Vin reaches the threshold voltage Vtha, a state change is produced in each input buffer circuit 4101 to 410N of the input buffer circuit block 410; if the input voltage Vin reaches the threshold voltage Vthb, a state change is produced in each input buffer circuit 4201 to 420N of the input buffer circuit block 420; and if the input voltage Vin reaches the threshold voltage Vthc, a state change is produced in each input buffer circuit 4301 to 430N of the input buffer circuit block 430. That is, although the input buffer circuit blocks 410, 420, 430 receive the common input voltage Vin, since the threshold voltages Vtha, Vthb, Vthc are different, the timings to produce state changes become different. This point has been shown in (B), (C) and (D) of FIG. 5.

Supposing that flow-through currents produced in the input buffer circuits 410, 420, 430 by such state changes as it10, it20, it30, then these flow-through currents it10, it20, it30 also correspond to the timings t1, t2, t3 and produce peak values with the above-described time difference Δt (FIG. 5). Moreover, supposing that each flow-through current of the input buffer circuit blocks 410, 420, 430 from the power source circuit 14 as it10, it20, it30, respectively, then an added flow-through current its0 takes the same form as in (E) of FIG. 5 such that its peak value is suppressed low with less fluctuation, so that noise generation caused by a flow-through current it0 can be suppressed and accordingly malfunctions caused by the noise of LSI2 can be avoided.

### Third Embodiment

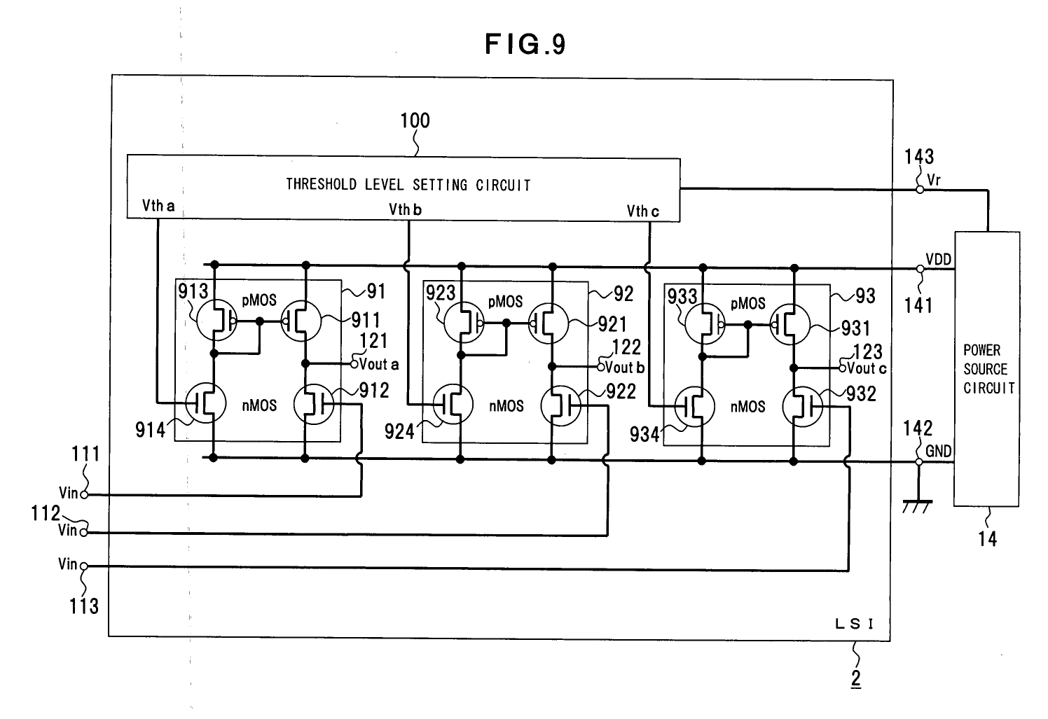

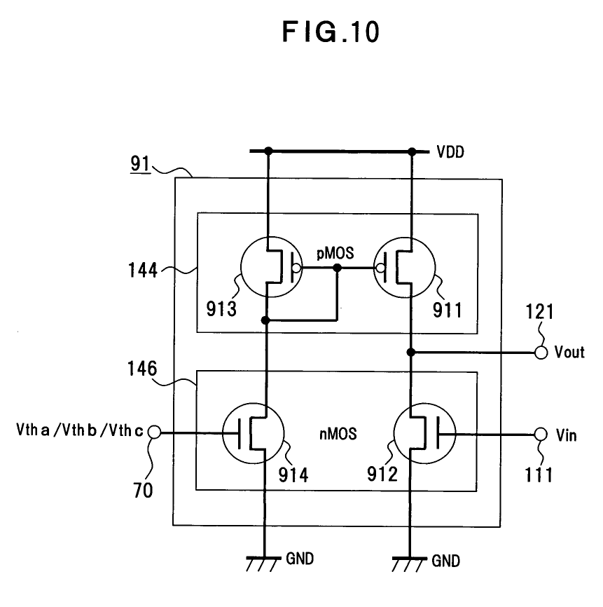

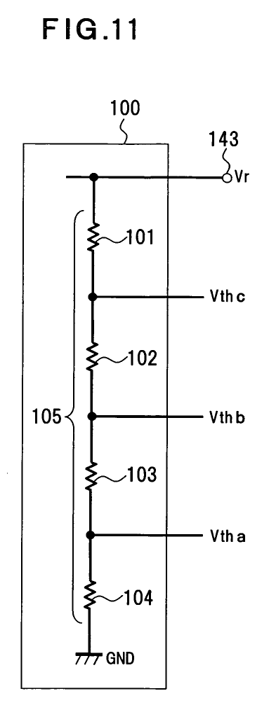

Next, a third embodiment of the present invention will be described with reference to FIGS. 9, 10 and 11. FIG. 9 is a circuit diagram showing a configuration example of an LSI2 with a plurality of built-in input buffer circuits having different threshold levels; FIG. 10 is a circuit diagram showing a configuration example of each input buffer circuit; and FIG. 11 is a circuit diagram showing a configuration example of a threshold level setting circuit.

Regarding semiconductor integrated circuits such as an LSI, settings of threshold levels to elements or circuits such as invertors can be achieved by circuit configurations of electronic circuits as well, other than the above-described configurations of constants for elements. Therefore, in this embodiment, to each input buffer circuit 91, 92, 93, each threshold voltage Vtha, Vthb, Vthc is set to be different from each other depending on circuit configurations of electronic circuits, and in order to set these threshold voltages Vtha, Vthb, Vthc, a threshold level setting circuit 100 is provided.

In this LSI2, the input buffer circuit 91 is comprised of transistors 911, 912, 913, 914. The transistors 911, 913 are comprised of the P-channel MOS transistor, whereas the transistors 912, 914 are comprised of the N-channel MOS transistor. The transistors 911, 912 form a CMOS circuit, and similarly the transistors 913, 914 form a CMOS circuit as well. At the gate of the transistor 912, an input terminal 111 is formed and the input voltage Vin is applied thereto, while to the gate of the transistor 914, the threshold voltage Vtha (Vthb or Vthc) is applied from the threshold level setting circuit 100. Furthermore, at the drain to which each transistor 911, 912 is connected in common, an output terminal 121 is formed to obtain the output voltage Vouta. In addition, to the source of the transistors 911, 913, the voltage VDD is applied from the power source circuit 14 via a feeding terminal 141. The source of the transistors 912, 914 is connected to a ground (GND) via a ground terminal 142.

The input buffer circuit 92 is comprised of transistors 921, 922, 923, 924, whereas the input buffer circuit 93 is comprised of transistors 931, 932, 933, 934. Although the threshold voltages Vthb, Vthc are different and the output voltages Voutb, Voutc are obtained in response to the threshold voltages, other than that, configurations and connections of these elements, and connection relationships with the power source circuit 14 and with the threshold level setting circuit 100 are the same as those of the input buffer circuit 91.

Furthermore, the threshold level setting circuit 100 can obtain different threshold voltages Vtha, Vthb, Vthc by configuring a voltage dividing circuit 105, for example, as shown in FIG. 11, with the use of resistances 101, 102, 103, 104, to divide a constant voltage Vr applied from the power source circuit 14 via a feeding terminal 143.

According to such a configuration, when the input voltage Vin is applied in common to the input terminals 111, 112, 113, as shown in (A) of FIG. 5, electrical state changes are produced in the input buffer circuits 91, 92, 93 by the relationship of magnitude between this input voltage Vin and the threshold voltages Vtha, Vthb, Vthc, and since these threshold voltages Vtha, Vthb, Vthc are differentiated, there arise differences in the timings to produce state changes.

Regarding such input buffer circuits 91, 92, 93, setting of threshold voltages Vtha, Vthb, Vthc, and differences in the timings of state changes produced on receiving the input voltage Vin will be described with reference to FIG. 10.

As shown in FIG. 10, in the input buffer circuit 91, since the gate of the transistor 911 and the gate of the transistor 913 as well as the drain are connected in common, the transistors 911, 913 constitute a current mirror circuit 144. In addition, since each source of the transistors 912, 914 is connected to the common ground, the transistors 912, 914 form an actuating pair 146. Consequently, the current mirror circuit 144 constitutes a load to the actuating pair 146.

To simplify the description, it is assumed that any of the threshold voltages Vtha, Vthb, Vthc that are differentiated by the threshold level setting circuit 100 (FIG. 10) is applied to the transistor 914 of this input buffer circuit 91.

In the case where the threshold voltage Vtha is set to the transistor 914, for example, and when the input voltage Vin is lower than the threshold voltage Vtha or equal to zero (Vin=0) , the transistor 914 is brought into the conduction state. With this conduction, both the transistors 911, 913 are brought into the conduction state, since each gate is dropped to the ground potential via the transistor 914. As a result of this, to the transistors 913, 914, a current in response to the threshold voltage Vtha that is set at the gate of the transistor 914 flows, and at the output terminal 121, the high (H) level output voltage Vouta in response to the threshold voltage Vtha is obtained.

Further, when the input voltage Vin is higher (H) than the threshold voltage Vtha, the transistor 912 is brought into the conduction state, whereas the transistor 911 is brought into the cutoff state and the output voltage Vouta of the output terminal 121 falls to a low (L) level. At this time, similarly the transistors 913, 914 shift from the conduction state to the cutoff state.

Such state changes are also produced in the same way when the threshold voltages Vthb, Vthc are set. The difference is that there arise differences in the conduction timings because of relationship between the input voltage Vin and the threshold voltages Vtha, Vthb, Vthc. That is, as shown in FIG. 5, when the level change of the input voltage Vin reaches the threshold voltages Vtha, Vthb, Vthc (at the timings of t1, t2, t3), a state change is produced and the flow-through current it1 flows through the transistors 911, 912.

When these behaviors are applied to the input buffer circuits 91, 92, 93 in which different threshold voltages Vtha, Vthb, Vthc have been set (FIG. 9), even the common input voltage Vin is received, owing to the difference of conduction timings brought by the different threshold voltages Vtha, Vthb, Vthc, the flow-through currents it1, it2, it3 flowing from the power the power source circuit 14 into each input buffer circuit 91, 92, 93 flow at different timings and superposition of peak values can be avoided. As a result of this, even if the transistors 911, 921, 931 conduct simultaneously, the peak value of the flow-through currents is suppressed low and its fluctuation is suppressed as well, so that noise generation caused by the flow-through current can be suppressed and accordingly malfunctions caused by the noise of LSI2 can be avoided.

In this way, similarly, the different threshold voltages Vtha, Vthb, Vthc can be set as well by the circuit configuration, as shown in FIG. 9, and accordingly the timings to produce flow-through currents can be differentiated.

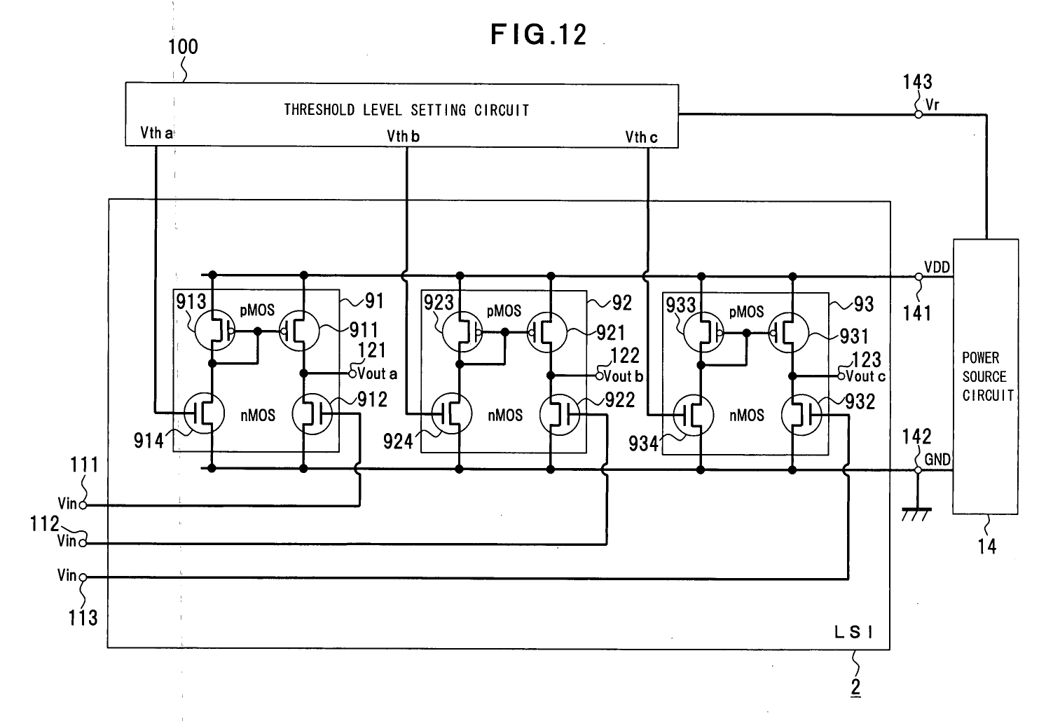

Although in this embodiment, the threshold level setting circuit 100 is provided as an internal circuit of the LSI2, the same functionality can be obtained as well by configuring the circuit 100 as an external circuit of the LSI2, as shown in FIG. 12.

### Fourth Embodiment

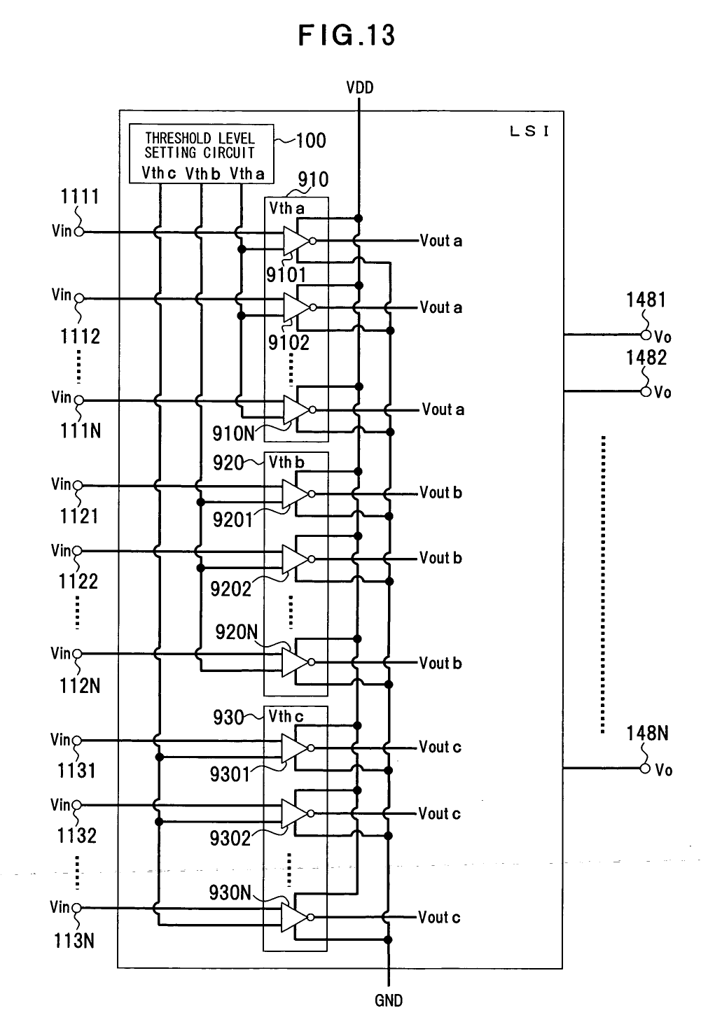

Next, a fourth embodiment of the present invention will be described with reference to FIG. 13. FIG. 13 is a diagram showing a configuration example of an LSI with a built-in input buffer circuit having different threshold levels set by a threshold level setting circuit.

In this LSI2, as a plurality of input buffer circuit blocks having different threshold levels, three pairs of input buffer circuit blocks 910, 920, 930 are provided, for example, and each input buffer circuit block 910, 920, 930 is comprised of input buffer circuits 9101, 9102, . . . 910N; input buffer circuits 9201, 9202, . . . 920N; and input buffer circuits 9301, 9302, . . . 930N, for example, as a plurality of input buffers. In this embodiment, by the common threshold level setting circuit, to the input buffer circuit block 910, the threshold voltage Vtha is set; to 920, Vthb is set; and to 930, Vthc is set. Magnitude of threshold voltages is set as Vtha<Vthb<Vthc, for example.

Subsequently, to input terminals 1111, 1112, . . . 111N, 1121, 1122, . . . 112N, 1131, 1132, . . . 113N, for example, the input voltage Vin is applied as input such as digital signals of multiple bits; the output voltages Vouta, Voutb, Voutc can be obtained in each input buffer circuit block 910, 920, 930; and output voltages Vo can be obtained from output terminals 1481, 1482, . . . 148N.

According to such a configuration, as shown in (A) of FIG. 5, if the input voltage Vin is applied in common to the input terminals 1111 to 111N, 1121 to 112N, 1131 to 113N, then due to the relationship of magnitude between this input voltage Vin and the threshold voltages Vtha, Vthb, Vthc, electrical state changes are produced in the input buffer circuit blocks 910, 920, 930. Since the threshold voltages Vtha, Vthb, Vthc are differentiated, there arise differences in the timings to produce electrical state changes.

Specifically, if the input voltage Vin reaches the threshold voltage Vtha, a state change is produced in each input buffer circuit 9101 to 910N of the input buffer circuit block 910; if the input voltage Vin reaches the threshold voltage Vthb, a state change is produced in each input buffer circuit 9201 to 920N of the input buffer circuit block 920; and if the input voltage Vin reaches the threshold voltage Vthc, a state change is produced in each input buffer circuit 9301 to 930N of the input buffer circuit block 930. This has been shown in (B), (C) and (D) of FIG. 5.

Supposing that flow-through currents produced in the input buffer circuit blocks 910, 920, 930 by such state changes as it10, it20, it30, then these flow-through currents it10, it20, it30 also correspond to the timings t1, t2, t3 and produce peak values with the above-described time difference Δt (FIG. 5). Moreover, supposing that each flow-through current of the input buffer circuit blocks 910, 920, 930 from the power source circuit 14 as it10, it20, it30, respectively, then the added flow-through current its0 takes the same form as in (E) of FIG. 5 such that its peak value is suppressed low with less fluctuation, so that noise generation caused by the flow-through current it0 can be suppressed and accordingly malfunctions caused by the noise of LSI2 can be avoided.

Although in this embodiment, the threshold level setting circuit 100 is comprised as the internal circuit of the LSI2, the same functionality can be obtained as well by configuring the circuit 100 as an external circuit of the LSI2, as shown in FIG. 12.

### Fifth Embodiment

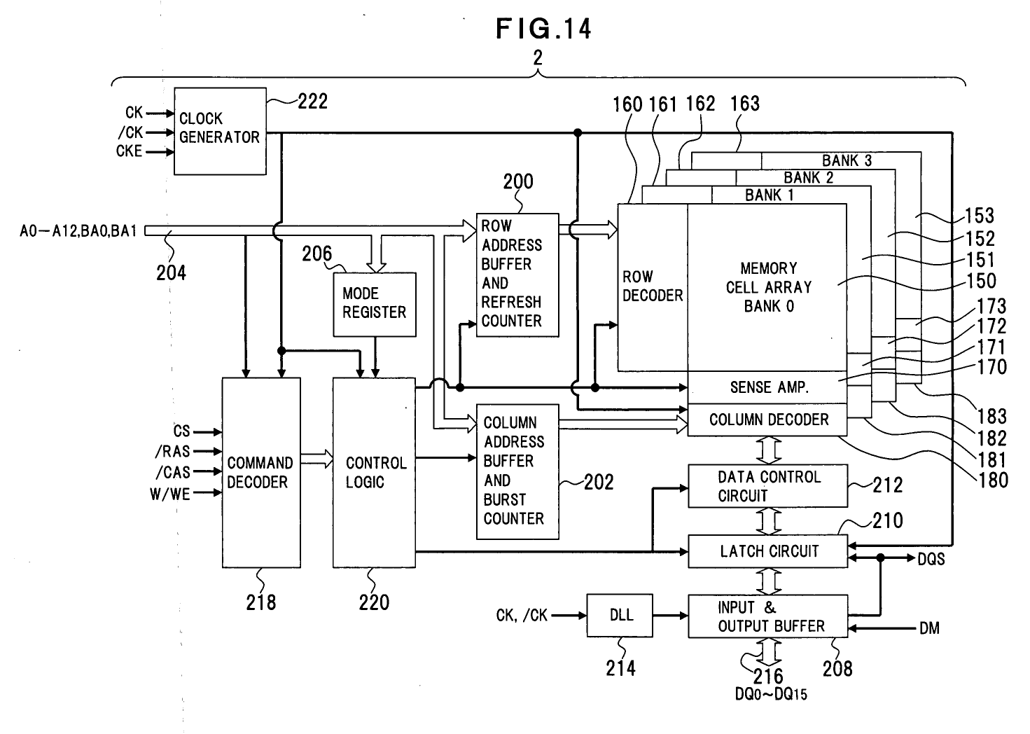

Next, a fifth embodiment of the present invention will be described with reference to FIG. 14. FIG. 14 is a diagram showing an example of an LSI equipped with an input buffer circuit having different threshold levels.

This LSI2 is one example of memory LSI, and in this LSI2, a plurality of memory cell array 150, 151, 152, 153 are provided as memory device. The memory cell array 150 to 153 constitute bank 0 to bank 3, respectively. To each memory cell array 150 to 153, row decoders 160, 161, 162, 163, sense amplifiers 170, 171, 172, 173, and column decoders 180, 181, 182, 183 are provided respectively. The sense amplifiers 170 to 173 are provided in order to amplify data signals.

Furthermore, on the row decoders 160 to 163 side, a row address buffer and refresh counter 200 is provided, whereas on the column decoders 180 to 183 side, a column address buffer and burst counter 202 is provided. To these counters 200, 202, address data is added from a plurality of input pins 204 (A0 to A12, BA0, BA1). The address data from the input pins 204 is added to a mode register 206 as well. By digital signals of two bits added to the input pins BA0, BA11, the memory cell array 150 to 153 constituting the banks 0 to 3 is selected.

Moreover, in the column decoders 180 to 183, an input/output buffer 208, a latch circuit 210, and a data control circuit 212 are provided. In the input/output buffer 208, a DLL (Delay Locked Loop) 214 for phase adjustment is provided. At the input/output buffer 208, input/output of data is performed via data input/output pins 216 (DQ, DQ0 to DQ15).

In addition, a command decoder 218, a control logic circuit 220, and a clock generator 222 are provided. To the command decoder 218, a Chip Select signal /CS, a Row Address Signal /RAS, a Column Address Signal /CAS, and a Write Enable signal W/WE are added as a plurality of input data, and input buffer circuits are provided for these data.

In the LSI2 comprising such memory LSI, if blocks are formed by setting different threshold levels for input buffer circuits of the row address buffer and refresh counter 200 and the column address buffer and burst counter 202 that are connected to the input pins 204; and for an input buffer circuit and an output buffer circuit of the input/output buffer 208 that is connected to the data input/output pins 216, then as has been above described, conduction timings are displaced by the differentiation of the threshold voltages, and consequently, superposition of peak values of the flow-through currents can be prevented and its fluctuation can be suppressed as well.

Moreover, by dividing data from the input pins 204 (A0 to A12) or the data input DQ0 to DQ15 from the data input/output pin (DQ) 216 appropriately, and by differentiating the threshold level of the input buffer circuit or the output buffer circuit, a plurality of values can be set. For example, to the input data (DQ0 to DQ15), by setting the threshold voltage Vtha corresponding to the divided input data (DQ0 to DQ7); and by setting the threshold voltage Vthb corresponding to the divided input data (DQ8 to DQ15), superposition of peak values of the flow-through currents can be avoided, and its fluctuation can be suppressed as well. As a consequence, the noise caused by the flow-through currents and its effect can be avoided, and malfunctions of LSI2 can be avoided.

### Other Embodiments

Next, other embodiments and their features will be listed hereinbelow.

(1) In the above-described embodiments, input buffer circuits are exemplified, however, by configuring as an output buffer circuit with the same configuration and by setting different threshold levels, superposition of peak values of the flow-through currents can be avoided and its fluctuation can be suppressed in the same way. As a result, noise generation and its effect can be avoided, and accordingly malfunctions of LSI2 can be prevented.

(2) In the above-described embodiments, CMOS circuits are exemplified, however, the present invention can be applied to invertors and switching circuits other than CMOS circuits, not limited to CMOS circuits.

(3) FET and CMOS circuits are exemplified as elements or circuits producing state changes by input, however, the elements or circuits producing state changes by input include various types of elements or circuits such as bipolar transistors or inverter circuits using the bipolar transistors.

(4) In the above-described embodiments, description is given for the case in which three threshold voltages Vtha, Vthb, Vthc are set as different threshold voltages in the semiconductor integrated circuit including a plurality of elements or circuits, however, the number of threshold voltages to be set can be set as less than or equal to three or greater than or equal to four. For the setting of threshold levels, it can be performed in terms of input conditions such as level changes of input voltages, operation frequency of input buffer circuits, and circuit conditions such as driving voltage. If the number of threshold voltages to be set increases, the timings of state changes produced in the elements or circuits varies that much, so that the number and the threshold voltage can be selected arbitrarily within the bounds of not harming the functionality of circuits.

A most preferred embodiment and the like of the present invention have been described above. However, the present invention is not limited to the above description; it goes without saying that various modifications and alterations may be made by a person skilled in the art on the basis of the gist of the invention that is described in the claims and disclosed in the detailed description of the invention, and that such modifications and alterations are included in the scope of the present invention.

Since the present invention is configured such that the semiconductor integrated circuit includes a plurality of elements or circuits having different threshold levels, state changes are produced at different timings depending on the threshold levels even if a common input is applied thereto simultaneously. Therefore, the present invention is useful, since suppression of currents caused by state changes can be avoided; noise generation or noise amplitude by the currents can be reduced; and malfunctions of the semiconductor integrated circuit can be prevented as well as its reliability can be enhanced.

The entire disclosure of Japanese Patent Application No. 2005-80702 including specification, claims, drawings and summary are incorporated herein by referencing its entirety.

What is claimed is:

1. A semiconductor integrated circuit comprising a plurality of elements or circuits with different threshold levels, configured to produce state changes at different timings in accordance with the threshold levels, in the case where a common input is applied to those elements or circuits simultaneously.

2. The semiconductor integrated circuit of claim 1, wherein the elements are transistors.

3. The semiconductor integrated circuit of claim 1, wherein the circuits are CMOS circuits.

4. The semiconductor integrated circuit of claim 1, wherein the threshold levels are set by constants of the elements or circuits.

5. The semiconductor integrated circuit of claim 1, wherein the threshold levels are set by concentration of impurities in substrate area of the elements.

6. The semiconductor integrated circuit of claim 1, wherein the threshold levels are set by the distance between the substrate area in which a channel of the elements is formed and a gate of the elements.

7. The semiconductor integrated circuit of claim 1, further comprising a threshold level setting circuit that sets different threshold levels to the elements or circuits.

8. A semiconductor integrated circuit comprising a plurality of circuits that produce state changes in accordance with inputs, the circuits further comprising:
a plurality of actuating pairs consisting of a first transistor to which different threshold voltages are inputted and a second transistor to which an input voltage is applied;
and
current mirror circuits provided for each of the actuating pairs to constitute loads of the first and second transistors.

9. A semiconductor integrated circuit comprising a single or a plurality of CMOS circuits that produce state changes in accordance with inputs, wherein the CMOS circuit has been set with different threshold levels such that state changes are produced at different timings in accordance with difference of the threshold levels, upon receiving a common input simultaneously.

10. A semiconductor integrated circuit comprising a single or a plurality of CMOS circuits that produce state changes in accordance with inputs, wherein the CMOS circuit has been set with different threshold levels such that superposition of peak values of flow-through currents flowing among the elements are avoided by differentiating timings of the rise and fall of the flow-through currents in accordance with difference of the threshold levels, upon receiving a common input simultaneously.

11. A noise reduction method for a semiconductor integrated circuit comprising a plurality of elements or circuits, the noise reduction method setting different threshold levels to the elements or circuits such that state changes are produced at different timings in accordance with the threshold levels, upon receiving a common input simultaneously.
